(19) United States
(12) Patent Application Publication
(10) Pub. No.: US 2023/0062123 A1
(43) Pub. Date: Mar. 2, 2023

(54) APPARATUS FOR FORMING FILM ON SUBSTRATE AND METHOD FOR FORMING FILM ON SUBSTRATE

(71) Applicant: TOKYO ELECTRON LIMITED, Tokyo (JP)

(72) Inventors: Toshio TAKAGI, Nirasaki City (JP); Takuya KAWAGUCHI, Nirasaki City (JP); Takanobu HOTTA, Nirasaki City (JP); Hideaki YAMASAKI, Nirasaki City (JP); Takaya YAMAUCHI, Nirasaki City (JP)

(21) Appl. No.: 17/896,904

(22) Filed: Aug. 26, 2022

(30) Foreign Application Priority Data
Aug. 30, 2021 (JP) 2021-140030

(51) Int. Cl. C23C 16/455; C23C 16/06; H01L 21/3205; C23C 16/458

(52) U.S. Cl. CPC C23C 16/45591; C23C 16/06; H01L 21/32051; C23C 16/4585; C23C 16/4586; C23C 16/45527; C23C 16/45544

(57) ABSTRACT

An apparatus for forming a film on a substrate includes: a processing container in which a reaction gas is supplied to a surface of the substrate; a stage installed in the processing container, configured to place the substrate and including a heater; a lifting shaft connected to an external lifting mechanism via a through port formed in the processing container; a casing installed between the processing container and the lifting mechanism and covering the lifting shaft; a lid member disposed to surround the lifting shaft with a gap interposed between the lifting shaft and the lid member, and installed in the processing container; a purge gas supplier configured to supply a purge gas into the casing; and a guide member disposed at a position facing the gap that opens toward an interior of the processing container and including a guide surface configured to guide the purge gas.

### CROSS-REFERENCE TO RELATED APPLICATION

This application is based upon and claims the benefit of priority from Japanese Patent Application No. 2021-140030, filed on Aug. 30, 2021, the entire contents of which are incorporated herein by reference.

### TECHNICAL FIELD

The present disclosure relates to an apparatus for forming a film on a substrate and a method for forming a film on the substrate.

### BACKGROUND

A chemical vapor deposition (CVD) method and an atomic layer deposition (ALD) method are known as methods for forming a film on a semiconductor wafer (hereinafter, referred to as a “wafer”) which is a substrate. Patent Document 1 describes a film forming apparatus in which a substrate is provided on a plate including an accommodation surface for accommodating the substrate in a substrate processing chamber, and a film forming process is performed by a CVD method. In addition, Patent Document 2 describes a film forming apparatus in which a wafer is placed on a stage disposed in a processing container and a film forming process is performed by an ALD method. These are single-wafer type film forming apparatuses that form a film on each wafer to be processed one by one.

### PRIOR ART DOCUMENT

### Patent Document

Patent Document 1. Japanese National Publication of International Patent No. H09-509534
Patent Document 2: International Publication No. WO 2014/178160

### SUMMARY

According to one embodiment of the present disclosure, there is provided an apparatus for forming a film on a substrate. The apparatus includes: a processing container in which a reaction gas is supplied to a surface of the substrate in a vacuum atmosphere to perform a film forming process; a stage installed in the processing container, configured to place the substrate thereon, and including a heater configured to heat the substrate; a lifting shaft installed to extend in a vertical direction while supporting the stage from a bottom surface side of the stage, and connected to an external lifting mechanism via a through port formed in the processing container; a casing installed between the processing container and the lifting mechanism and covering a periphery of the lifting shaft; a lid member disposed to surround the lifting shaft with a gap interposed between a side peripheral surface of the lifting shaft and the lid member, and installed in the processing container over an entire circumference such that communication between a lower side space and an upper side space of the lid member is blocked in a portion other than the gap; a purge gas supplier configured to supply a purge gas into the casing, and a guide member disposed at a position facing an end portion of the gap that opens toward an interior of the processing container and including a guide surface configured to guide the purge gas supplied to the casing such that the purge gas flows into the processing container through the gap and then flows away from a direction toward a rear surface of the stage.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional side view illustrating an embodiment of an apparatus for forming a film on a substrate according to the present disclosure.

FIG. 2 is an exploded perspective view illustrating a lid member, a guide member, and the like installed in a processing container constituting the apparatus.

FIG. 3 is a vertical cross-sectional side view of a connection portion between a processing container and a bellows constituting the apparatus.

FIG. 4 is a vertical cross-sectional side view illustrating the action of the guide member.

FIG. 5 is a vertical cross-sectional side view illustrating the action of a comparative example in which the guide member is not installed.

FIGS. 6A and 6B are plan views each showing a temperature distribution of a substrate placed on a stage.

FIG. 7 is a vertical cross-sectional side view illustrating another example of the guide member.

FIG. 8 is a vertical cross-sectional side view illustrating still another example of the guide member.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Film Forming Apparatus>

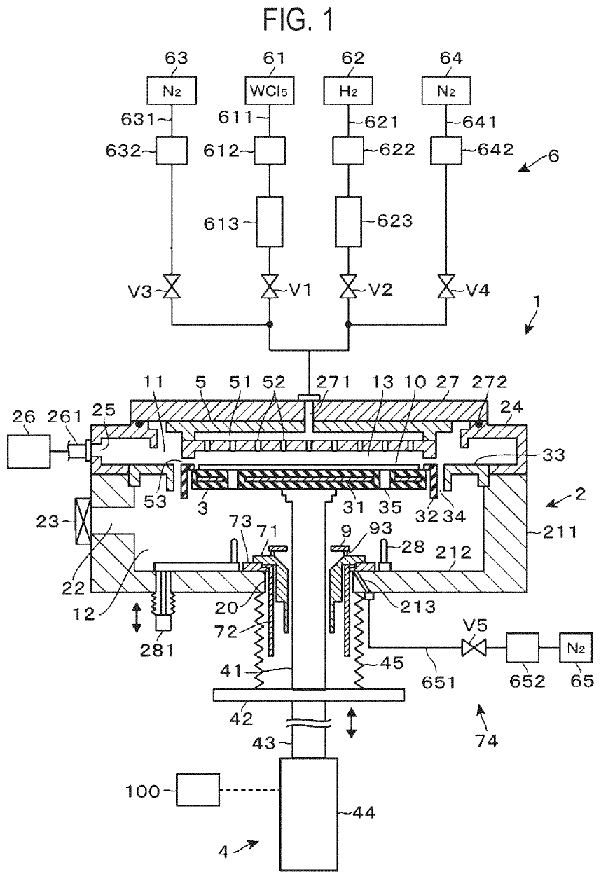

The configuration of an apparatus for forming a film on a substrate (hereinafter referred to as a “film forming apparatus”) according to an embodiment of the present disclosure will be described with reference to FIG. 1. The film forming apparatus 1 is an apparatus for performing a film forming process by supplying a reaction gas to, for example, a surface of a circular wafer 10 having a diameter of 300 mm, as a film forming target, under a vacuum atmosphere.

As illustrated in FIG. 1, the film forming apparatus 1 is made of a metal such as aluminum, and includes a processing container 2 having a substantially circular planar shape. A carry-in/out port 22 for delivering a wafer 10 to/from an external vacuum transport chamber (not illustrated) is installed on the side surface of the processing container 2 to be openable/closable by a gate valve 23.

Above the carry-in/out port 22, an exhaust duct 24 having a square shape in vertical cross section is installed to be stacked on a side wall 211 constituting the main body of the processing container 2. The inner peripheral surface of the exhaust duct 24 is opened in a slit shape toward the interior of the processing container 2 along the circumferential direction thereof, and an exhaust port 25 is formed in the outer wall surface of the exhaust duct 24. An exhaust mechanism 26 including a vacuum pump, a pressure control valve, and the like is connected to the exhaust port 25 via an exhaust path 261 so that the interior of the processing container 2 is set to a vacuum atmosphere. A disk-shaped ceiling plate 27 is installed on the top surface of the exhaust duct 24 via an O-ring 272 to close a circular opening.

### <Stage>

A stage 3 on which a wafer 10 is placed is disposed at a position inside the exhaust duct 24 in the processing container 2. The stage 3 is configured as a disk that has a size larger than the wafer 10, and is made of, for example, ceramic or metal. A heater 31 for heating the wafer 10 is embedded in the stage 3, and a cover member 32 surrounding the side peripheral surface of the stage 3 is installed on the lateral side of the stage 3.

In addition, an inner ring 33 is installed between the cover member 32 and the side wall 211 of the processing container 2, whereby the interior of the processing container 2 is divided into a space 11 above the stage 3 and a bottom area 12 below the stage 3. A through-flow path 34 for communicating the atmosphere in the bottom area 12 with the exhaust duct 24 is formed between the cover member 32 and the inner ring 33.

Below the stage 3, support pins 28 that support and lift a wafer 10 from the bottom surface side when the wafer 10 is delivered are installed to be movable upward and downward by the lifting mechanism 281. Reference numeral 35 in FIG. 1 indicates through holes for the support pins 28.

### <Lifting Shaft and Lifting Mechanism>

A rod-shaped lifting shaft 41 that penetrates the bottom surface of the processing container 2 and extends in the vertical direction is connected to the center of the bottom surface of the stage 3, and a lifting mechanism 4 that moves the lifting shaft 41 in the vertical direction is installed outside the processing container 2. The lifting mechanism 4 includes a lifting plate 42 which is horizontally arranged below the processing container 2 and to which the lower end of the lifting shaft 41 is connected, a cylinder rod 43, and a motor 44. In this way, the stage 3 is configured to be movable upward and downward between a processing position (the position illustrated in FIG. 1) where a film is formed on a wafer 10 and a delivery position where the wafer 10 is delivered to and from an external transport mechanism (not illustrated) through the carry-in/out port 22 by the lifting mechanism 4.

### <Through Port and Casing>

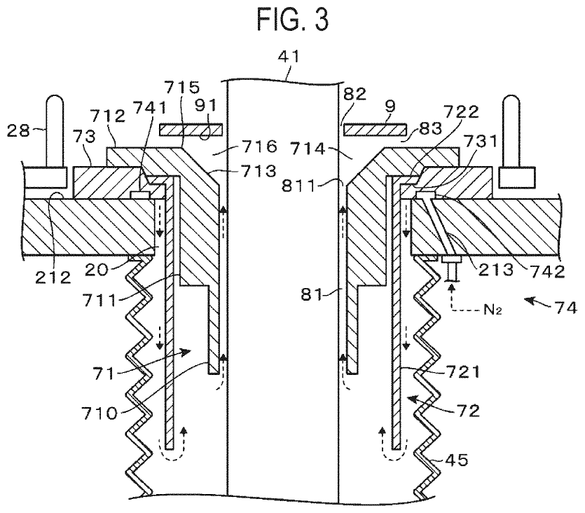

As illustrated in FIGS. 1 and 3, a through port 20 through which the lifting shaft 41 passes is formed in the bottom surface 212 of the processing container 2. A casing that covers the periphery of the lifting mechanism 4 is installed between the processing container 2 and the lifting mechanism 4, for example, between the opening edge of the through port 20 and the lifting plate 42. The casing in this example includes a bellows 45 that separates the atmosphere inside the processing container 2 from the exterior and expands and contracts as the lifting plate 42 moves upward and downward, and the bellows 45 is installed to cover the periphery of the lifting shaft 41 from the lateral side.

### <Shower Head>

A shower head 5 is disposed on the bottom surface of the ceiling plate 27 in the processing container 2 to face the wafer 10 placed on the stage 3. The shower head 5 includes a gas diffusion space 51, and a large number of gas ejection ports 52 are dispersed and formed on the lower surface of the gas diffusion space 51. Gas is supplied to the shower head 5 from the gas supply system 6 via the gas introduction path 271 formed in the ceiling plate 27. The outer edge of the shower head 5 extends downward to form an exhaust opening 53 between the shower head 5 and the cover member 32, and to form a processing space 13 between the stage 3 and the shower head 5. In this way, the top surface of the stage 3 and the bottom surface of the stage 3 are exposed to the processing space 13 and the bottom area 12, respectively.

### <Gas Supply System>

The gas supply system 6 will be described by taking as an example a case where a tungsten film (W film) is formed on a wafer 10. The film forming apparatus 1 of this example is configured to alternately supply two types of gases as reaction gases to the processing container 2 to form a W film by an ALD method. As the reaction gases, a raw material gas containing W and a reducing reaction gas (reducing gas) containing hydrogen may be used.

As the raw material gas, for example, tungsten pentachloride (WCl₅) gas is used, and the supply source 61 of WCl₅ is connected to the shower head 5 via a raw material gas supply path 611 and the gas introduction path 271. As the reducing gas, for example, hydrogen gas (H₂ gas) is used, and a H₂ gas source 62 is connected to the shower head 5 via a reaction gas supply path 621 and the gas introduction path 271.

The raw material gas supply path 611 and the reaction gas supply path 621 are installed with valves V1 and V2 for performing gas supply/interruption, flow rate adjusters 612 and 622 for adjusting a gas supply amount, and storage tanks 613 and 623, respectively. The WCl₅ gas and the H₂ gas are temporarily stored in the storage tanks 613 and 623, respectively, boosted to a predetermined pressure in the storage tanks 613 and 623, and then supplied to the processing container 2.

In addition, the raw material gas supply path 611 and the reaction gas supply path 621 are connected to replacement gas sources 63 and 64, respectively, via replacement gas supply paths 631 and 641. As a replacement gas, an inert gas such as nitrogen gas (N₂ gas) or argon gas (Ar gas) may be used. The replacement gas supply paths 631 and 641 include flow rate adjusters 632 and 642 and gas supply/interruption valves V3 and V4, respectively.

### <Lid Member>

As illustrated in FIGS. 1 and 3, a lid member 71 is disposed in the through port 20 to surround the lifting shaft 41, and the lid member 71 is inserted between the processing container 2 and the lifting shaft 41 to close the through port 20. In addition, a tubular member 72 is disposed between the lid member 71 and the bellows 45, and furthermore, a ring member 73 for supporting the lid member 71 and the tubular member 72 is installed on the bottom surface 212 of the processing container 2.

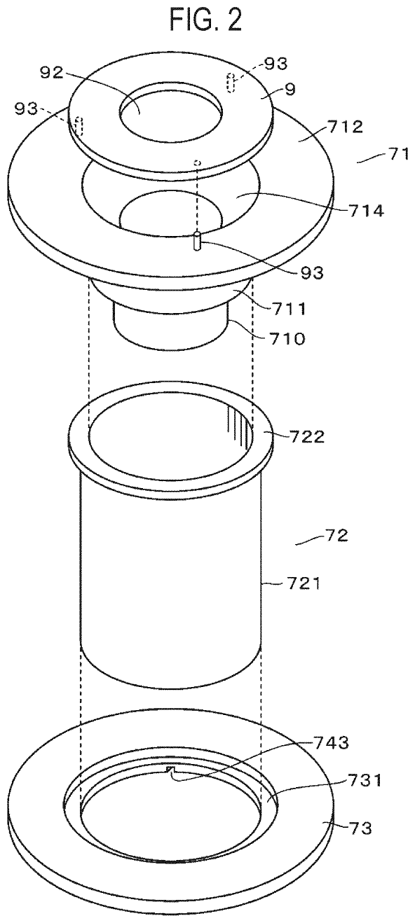

The lid member 71 is a tubular member that closes the space between the through port 20 formed in the bottom surface 212 of the processing container 2 and the lifting shaft 41. As illustrated in FIG. 2, a flange 712 is formed at the upper end of a cylindrical portion 711 forming the main body of the lid member 71, and the lid member 71 is disposed between the through port 20 and the lifting shaft 41 by engaging the bottom surface of the flange 712 with the ring member 73. The top surface of the flange 712 is formed substantially horizontally.

In the lid member 71 in this example, the lower portion of the cylindrical portion 711 is formed as a sleeve 710 having a small thickness dimension. The inner peripheral surface of the cylindrical portion 711 and the inner peripheral surface of the sleeve 710 are continuous to define the inner peripheral surface of the lid member 71. In addition, the top surface of the lid member 71 includes a recess 714 having a tapered surface 713, and the opening diameter of the tapered surface 713 gradually increases from the lower side to the upper side. The recess 714 is formed in the center of the lid member 71, the opening diameter of the recess 714 increases as the distance from the lifting shaft 41 increases, and the edge portion 715 of the opening (upper edge of the tapered surface 713) is formed to be connected to the flange 712.

As illustrated in FIG. 3, the lid member 71 is disposed to form a first gap 81 between the side peripheral surface of the lifting shaft 41 and the inner peripheral surface of the lid member 71 (the cylindrical portion 711 and the sleeve 710), whereby the lifting shaft 41 is configured to be movable inside the lid member 71 in the vertical direction. The lid member 71 is installed to the processing container 2 over the entire circumference such that communication between the lower space of the lid member 71 (the space in the bellows 45) and the upper space (the space in the processing container 2) of the lid member 71 is blocked in a portion other than the first gap 81.

The tubular member 72 has a structure in which a flange 722 is provided at the upper end of a cylindrical main body 721, and is disposed between the lid member 71 and the bellows 45 by engaging the flange 722 with the ring member 73. As illustrated in FIG. 3, the tubular member 72 has a height dimension such that, when the lid member 71 and the tubular member 72 are disposed at predetermined positions, the lower end of the tubular member 72 is located below the lower end of the lid member 71 (the sleeve 710).

The ring member 73 is disposed and fixed around the through port 20 on the bottom surface 212 of the processing container 2, and is configured to support the lid member 71 and the tubular member 72 by engaging with the flanges 712 and 722 of the lid member 71 and the tubular member 72. The ring member 73 includes, at the inner peripheral edge on the top surface side thereof, a step 731 for fitting and fixing the flange 722 of the tubular member 72 between the top surface of the ring member 73 and the bottom surface of the flange 712 of the lid member 71.

### <Purge Gas Supplier>

As illustrated in FIGS. 1 and 3, the film forming apparatus 1 includes a purge gas supplier 74 that supplies a purge gas into the bellows 45. On the bottom surface of the ring member 73, a groove (not illustrated) for supplying an inert gas, for example, N₂ gas, which is a purge gas, is formed inside the bellows 45. By fixing the ring member 73 on which the groove is formed on the bottom surface 212 of the processing container 2, the space surrounded by the groove and the processing container 2 becomes a purge gas flow path 741.

A port portion 742 provided at the base end side of the purge gas flow path 741 is connected to a purge gas supply path 213 formed in the processing container 2, and as illustrated in FIG. 1, the purge gas supply path 213 is connected to a purge gas source 65 via a pipe 651. The pipe 651 is provided with a gas supply/interruption valve V5 and a flow rate adjuster 652.

At the end of the purge gas flow path 741, for example, four purge gas ejection holes 743 (see FIG. 2) that open toward the inner peripheral surface of the ring member 73 are formed. These purge gas ejection holes 743 are arranged at substantially equal intervals along the circumferential direction of the inner peripheral surface of the ring member 73. The purge gas source 65, the purge gas supply path 213, the purge gas flow path 741, the purge gas ejection holes 743, and the like constitute the purge gas supplier 74 of the present embodiment.

The purge gas supplier 74 supplies the purge gas to the bottom area 12 of the processing container 2 via the bellows 45. Briefly explaining the flow of the purge gas in the bellows 45 with reference to FIG. 3, the purge gas supplied into the bellows 45 from the purge gas ejection holes 743 flows from the top to the bottom in the gap formed between the outer peripheral surface of the tubular member 72 and the inner peripheral surface of the bellows 45 as indicated by the broken line arrows. Next, the purge gas reaches the lower end of the tubular member 72, spreads in the space inside the bellows 45, and flows into a first gap 81 formed between the lifting shaft 41 and the lid member 71. Then, the purge gas flows upward in the first gap 81, flows into the processing container 2 as will be described later, and spreads in the bottom area 12. By supplying the purge gas to the bottom area 12 in this way, the penetration of a reaction gas supplied from the shower head 5 into the bottom area 12 via the through-flow path 34 is suppressed, and the infiltration of the reaction gas into the rear surface of the stage 3 is suppressed.

### <Guide Member>

As illustrated in FIGS. 1 to 3, a guide member 9 including a guide surface for guiding the flow of a purge gas is provided between the lid member 71 and the stage 3 in the bottom area 12. The guide member 9 is disposed at a position facing an end portion 811 of the first gap 81 that opens toward the interior of the processing container 2, and the guide surface serves to guide the purge gas to flow away from the direction toward the rear surface of the stage 3. As illustrated in FIG. 3, the end portion 811 of the first gap 81 is the upper end of the first gap 81 and is an annular opening that is formed between the side peripheral surface of the lifting shaft 41 and the inner peripheral surface of the lid member 71. Since the guide member 9 is arranged at a position above the end portion 811, the guide member 9 is in a state of facing the end portion 811.

As illustrated in FIG. 2, the guide member 9 is configured with an annular member. In this example, the annular member is made of a plate-shaped member having an even thickness, and the bottom surface thereof forms a guide surface 91. An opening 92 in the center of the guide member 9 forms a region through which the lifting shaft 41 passes, and the guide member 9 (the inner peripheral surface of the opening 92) is disposed to surround the lifting shaft 41 at a position above the lid member 71 with a second gap 82 formed between the guide member 9 and the side peripheral surface of the lifting shaft 41.

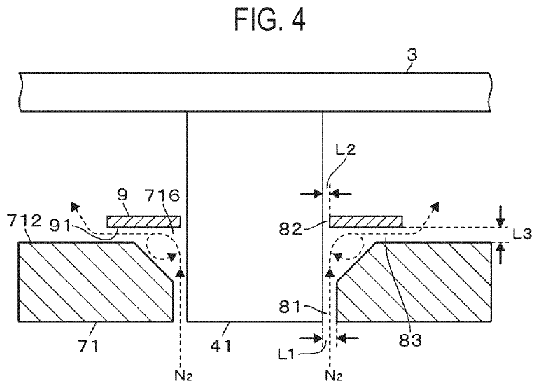

In addition, the guide member 9 is disposed at a position where the inner edge of the guide member 9 (the inner peripheral surface of the opening 92) is closer to the lifting shaft 41 side than the inner peripheral surface of the lid member 71. Therefore, the dimension L2 of the second gap 82 formed between the side peripheral surface of the lifting shaft 41 and the inner edge of the guide member 9 (see FIG. 4) is formed to be smaller than the dimension L1 of the first gap 81 formed between the side peripheral surface of the lifting shaft 41 and the lid member 71. As a result, the purge gas directed upward from the first gap 81 undergoes a large pressure loss when passing through the second gap 82, and thus the purge gas is inhibited from flowing toward the rear surface of the stage 3.

For example, the ratio of the dimension L1 of the first gap 81 to the dimension L2 of the second gap 82 (L1/L2) is set to a value within the range of 0.5 to 2.5, preferably to a value larger than 1 and equal to or smaller than 2.5. When the dimension L2 is made too small, it is difficult to adjust the position of forming the second gap 82 uniform along the circumferential direction of the lifting shaft 41 when assembling the film forming apparatus 1. When the dimension L2 is made too large, the action of the guide member 9 is difficult to work, and thus the amount of the purge gas passing through the second gap 82 may increase. However, the dimensions L1 and L2 are set in consideration of the type of the film forming process, the size of the film forming apparatus, and the dimension L3 of a third gap to be described later. For example, the dimension L1 of the first gap 81 is 1 mm to 5 mm, and the dimension L2 of the second gap 82 is 2 mm.

When viewed from the top surface side, the guide member 9 is provided to cover the opening of the recess 714 of the lid member 71, and the outer edge of the guide member 9 is disposed at a position outside the edge portion 715 of the opening of the recess 714. In this example, the region near the outer edge of the guide member 9 is provided to face the top surface of the flange 712 formed outside the recess 714. In this way, as illustrated in FIGS. 3 and 4, an annular space 716 having a substantially triangular shape in vertical cross section is formed between the bottom surface (guide surface 91) of the guide member 9 and the recess 714 in the lid member 71.

In addition, the guide member 9 is disposed at a position above the lid member 71 to form a gap (the third gap 83) through which the purge gas flows between the guide member 9 and the top surface of the lid member 71. The third gap 83 is a gap formed between the bottom surface of the guide member 9 and the top surface of the lid member 71 (the flange 712) at a position where the guide member 9 overlaps the lid member 71 (the flange 712) in a plan view. The dimension L3 of the third gap 83 is set to be larger than the dimension L2 of the second gap. In this way, the purge gas more easily flows out through the third gap 83, which has a smaller pressure loss than the second gap 82. With this configuration, the purge gas is guided to the guide surface 91 of the guide member 9 and flows laterally along the bottom surface 212 of the processing container 2.

For example, the ratio of the dimension L3 of the third gap 83 to the dimension L2 of the second gap 82 (L3/L2) is set to a value within the range of 1.5 to 3.5. This ratio is set depending on the flow rate of the purge gas, the type of the film forming process, and the like, but when the ratio exceeds the upper limit of the above range, the action of the guide member 9 that regulates the flow direction of the purge gas may be weakened. When the value of L3/L2 is below the lower limit of the above range, the difference in pressure loss when flowing through the second gap 82 and the third gap 83 may become smaller, and thus the proportion of the purge gas flowing into the bottom area 12 through the second gap 82 may increase. Therefore, it is preferable to set the value of L3/L2 to a value within the range described above. For example, the dimension L2 of the second gap 82 is 2 mm, and the dimension L3 of the third gap 83 is 5 mm. It may be summarized that it is preferable to set the relationship of the dimensions L1, L2, and L3 of the first, second, and third gaps 81, 82, and 83 to be L2<L1<L3.

As illustrated in FIGS. 1 and 2, the guide member 9 is installed on the top surface of the lid member 71 by, for example, a rod-shaped support member 93 in a region where the guide member 9 and the flange 712 of the lid member 71 face each other. For example, plural support members 93 are provided, and are arranged at plural locations in the circumferential direction of the lid member 71 at equal intervals in the circumferential direction. The size of the guide member 9, and the dimensions L1, L2, and L3 of the first gap 81, the second gap 82, and the third gap 83 are appropriately set depending on the sizes of the processing container 2, the bottom area 12, the stage 3 and the lifting shaft 41, the type of film forming process, and the like.

### <Controller>

As illustrated in FIG. 1, a controller 100 that the operation of each part of the film forming apparatus 1 is provided. The controller 100 is configured with, for example, a computer including a CPU and a storage part (not illustrated), and the storage part stores a program in which a group of steps (commands) for control necessary for forming a W film, which will be described later, are set. The program is stored in a storage medium such as a hard disk, a compact disk, a magneto-optical disk, a memory card, a nonvolatile memory, or the like, from which the program is installed in the computer.

### <Film Formation of W Film in Film Forming Apparatus>

Subsequently, a method of performing a film forming process of a W film by using the film forming apparatus 1 having the configuration described above will be described.

First, the interior of the processing container 2 is depressurized to a vacuum atmosphere in advance, then the stage 3 is lowered to the delivery position, and a wafer 10 is placed on the stage 3 heated to a film forming temperature by the heater 31 through a collaborative work between an external transport mechanism (not illustrated) and the support pins 28. In the film forming process of the W film using WCl₅ gas and H₂ gas as reaction gases, the film forming temperature is about 450 degrees C. In addition, a purge gas (N₂ gas) is supplied from the purge gas supplier 74 into the bellows 45 at a flow rate within the range of 4.5 liters/minute to 28 liters/minute (for example, at a flow rate of 28 liters/minute).

When the wafer 10 is placed on the stage 3, the gate valve 23 is closed, the stage 3 is raised to the processing position to form the processing space 13, and the pressure inside the processing container 2 is adjusted. Since the interior of the film forming apparatus 1 is evacuated through the exhaust duct 24 by the exhaust mechanism 26, the atmosphere in the processing space 13 flows into the exhaust duct 24 through the opening 53 formed between the shower head 5 and the cover member 32 and is exhausted to the exterior of the film forming apparatus 1. Meanwhile, the atmosphere of the bottom area 12 in the film forming apparatus 1 is also exhausted from the exhaust duct 24 through the through-flow path 34 by the exhaust of the exhaust mechanism 26.

Next, to the surface of the wafer 10 heated to the film forming temperature, supply of reaction gases (WCl₅ gas and H₂ gas) and a replacement gas (N₂ gas) is performed in the order of WCl₅ gas→N₂ gas→H₂ gas→N₂ gas via the gas supply system 6 and the shower head 5. As a result, the two types of reaction gases adsorbed on the wafer 10 react with each other to form a tungsten molecular layer, and the molecular layers are laminated to form a tungsten film (W film). In this way, the above-mentioned supply cycle of the reaction gases and the substitution gas is repeated dozens of times to hundreds of times to form a W film having a target film thickness. Thereafter, the supply of gases is stopped, the stage 3 is lowered to the delivery position, the gate valve 23 is opened, and the wafer 10 is taken out.

Next, the flow of a purge gas will be described. As described above, the purge gas that has flowed into the bellows 45 from the purge gas ejection holes 743 spreads over the entire space inside the bellows 45, and flows into the first gap 81 formed between the lifting shaft 41 and the lid member 71. Here, among the raw material gases, WCl₅ has a property of easily spreading, and some of the WCl₅ molecules may spread and enter the bottom area 12 against the flow of the purge gas flowing into the exhaust duct 24 through the through-flow path 34. When the WCl₅ molecules that have entered the bottom area 12 are decomposed and deposits are formed on the rear surface side of the stage 3, the heat capacity of the stage 3 becomes non-uniform in the plane, and uniform heating of the wafer W by the heater 31 may be hindered. When the heating temperature of the wafer W becomes non-uniform in the plane, the in-plane film thickness uniformity of the W film may also be deteriorated.

Therefore, the film forming apparatus 1 of this example supplies the purge gas at a relatively large flow rate of 28 liters/minute, which is about 6 times the flow rate in the related arts, in order to suppress the formation of deposits on the rear surface of the stage 3 due to the spreading of WCl₅ molecules. Such a large flow rate of purge gas vigorously flows upward (toward the stage 3) in the first gap 81 having a narrow gap size L1 at a high flow velocity. Then, the purge gas is ejected upward from the end portion 811 of the first gap 81, and the guide member 9 is disposed at the position where the purge gas is ejected. Therefore, the purge gas collides with the bottom surface (guide surface) of the guide member 9, changes the flow direction laterally along the guide surface 91 of the guide member 9 as indicated by the broken line arrows in FIG. 4, and flows through third gap 83.

Here, the second gap 82 is also formed between the lifting shaft 41 and the guide member 9, but the dimension L2 of the second gap 82 is set to be smaller than the dimension L3 of the third gap 83. In addition, the dimension L3 of the third gap 83 is formed to be larger than the dimension L1 of the first gap 81 and the dimension L2 of the second gap 82. Therefore, the pressure loss of the second gap 82 is larger than that of the third gap 83, and the purge gas is difficult to flow in the second gap 82. Therefore, most of the purge gas is likely to form a flow from the first gap 81 to the third gap 83. As a result, the purge gas changes its course laterally away from the direction toward the rear surface of the stage 3, and flows into the bottom area 12 along the bottom surface 212 of the processing container 2. Then, the purge gas flows toward the exhaust duct 24 through the through-flow path 34 while gently changing the flow direction in the bottom area 12. Even if a part of the purge gas passes through the second gap 82, the flow rate is very small and the momentum of the flow is weakened.

Some of the purge gas that has collided with the guide surface 91 of the guide member 9 changes the flow direction toward the space 716 formed between the guide member 9 and the recess 714 to form a vortex. The purge gas that has formed the vortex flows downward along the tapered surface 713 of the recess 714, then rises along the side peripheral surface of the lifting shaft 41, and reaches the guide member 9 again. Due to the formation of this vortex, the purge gas flows into the bottom area 12 in a state in which the momentum of the flow is further weakened and the flow velocity is reduced. Due to the action described above, the flow velocity of the purge gas when passing through the third gap 83 is lower than the flow velocity of the purge gas when flowing through the first gap 81, and the flow velocity when flowing into the bottom area 12 is further reduced.

When the inventors of the present application conducted a fluid simulation when the supply flow rate of the purge gas was set to 28 slm, the following flow of the purge gas was confirmed. That is, the purge gas flows laterally from the end portion of the third gap 83 into the bottom area 12 along the bottom surface 212 of the processing container 2. Thereafter, it was found that the purge gas that entered the wider space compared with the third gap 83 gradually changed the flow direction as the flow velocity is reduced, and flowed to the above-mentioned through-flow path 34. In addition, it was confirmed that the flow velocity when passing through the third gap 83 was reduced to about ⅕ of the flow velocity when flowing through the first gap 81, and the flow velocity when spreading into the bottom area 12 was further reduced.

As described above, the flow velocity when the purge gas flows into the bottom area 12 of the processing container 2 is low, but since the purge gas is supplied at a large flow rate, the bottom area 12 is filled with the purge gas and is in the state in which the pressure is increased to be higher than that in the processing space 13. As a result, during the period of the film forming process, by increasing the flow velocity of the purge gas when the purge gas passes through the through-flow path 34, it is possible to inhibit WCl₅ from entering the bottom area 12 through the through-flow path 34. Therefore, the infiltration of the reaction gases into the rear surface of the stage 3 is suppressed, and the formation of deposits on the rear surface of the stage 3 is suppressed.

According to the above-described embodiment, after flowing into the processing container 2 through the first gap 81 formed between the lifting shaft 41 and the lid member 71, the purge gas supplied into the bellows 45 is guided by the guide member 9 to flow away from the direction toward the rear surface of the stage 3.

Therefore, the purge gas ejected from the first gap 81 flows upward along the lifting shaft 41, and is hindered from colliding with the rear surface of the stage 3. This makes it possible to suppress a decrease in the temperature of the stage 3 at the position where the purge gas collides so that it is possible to suppress deterioration in the in-plane uniformity of the heated state of the stage 3. As a result, the wafer 10 placed on the stage 3 is heated by the heater 31 with good in-plane uniformity, so that the in-plane uniformity of the film forming process is maintained and the in-plane uniformity of the thickness and quality of the W film formed on the wafer W is also improved.

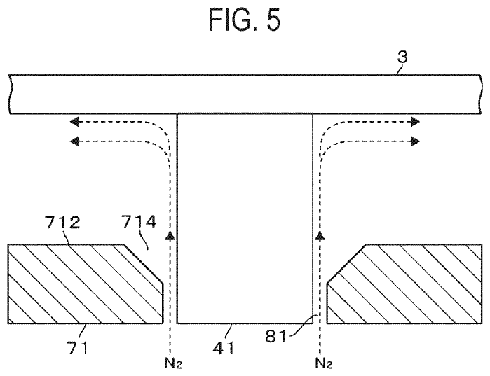

Here, as a comparative example, a configuration that does not include with the guide member 9 will be described with reference to FIG. 5. In this case, a large flow rate of purge gas flows at high speed through the first gap 81 having a narrow gap dimension L1, and then is rapidly ejected upward from the end portion 811 of the first gap 81, as indicated by the broken lines. Then, since the ejected purge gas reaches the rear surface of the stage 3 while maintaining the high flow velocity, the purge gas is concentrated in and collides with a partial region of the rear surface of the stage 3. Since the purge gas has a temperature lower than that of the stage 3, heat is taken away by the purge gas in the region where the purge gas collides, and the temperature of the stage 3 drops. Therefore, a region where the temperature is locally low is formed in the plane of the stage 3, and the in-plane uniformity of the overheated state of the stage 3 is deteriorated. As a result, the temperature distribution in the plane of the wafer 10 varies, and the film forming process proceeds non-uniformly in the plane.

With the miniaturization of semiconductor devices, the flow rates of reaction gases tend to increase in order to embed a film in a recess with a high aspect ratio. In this case, in order to suppress the infiltration of reaction gas molecules into the rear surface of the stage 3, the supply flow rate of the purge gas supplied to the bottom area 12 of the processing container 2 is increased by about 6 to 7 times from the flow rate in the related arts. As described above, this is because when deposits are formed on the rear surface of the stage 3 due to the infiltration of the reaction gas molecules, uneven heating of the stage 3 occurs and the in-plane temperature uniformity of the stage 3 is deteriorated. However, as described with reference to FIG. 5, when the flow rate of the purge gas is increased without taking any measures, the problem that the in-plane temperature uniformity of the stage 3 is deteriorated by the purge gas becomes apparent.

In addition, in the film forming process requiring precise temperature control, as being more affected by the formation of deposits on the rear surface of the stage 3, a slight temperature change of the wafer 10 has a great influence on the film thickness and the film quality. Therefore, in order to maintain the in-plane uniformity of the film forming process, there is also a process in which high in-plane uniformity is required for the temperature of the wafer. Therefore, in the configuration in which the purge gas is supplied through the gap between the lifting shaft 41 and the lid member 71 (the first gap 81), the technique capable of ensuring high in-plane uniformity with respect to the temperature of the stage 3 while increasing the flow rate of the purge gas is effective for improving the in-plane uniformity of the film forming process.

In this respect, in the configuration of the film forming apparatus 1 described with reference to FIGS. 1 to 4, it is possible to make the purge gas flow laterally from the third gap 83 into the bottom area 12 at a low speed. Therefore, even when a large flow rate of purge gas is supplied, it is possible to suppress the formation of a flow in which the purge gas collides with the stage 3 at a high speed, and to maintain the in-plane uniformity of the heated state of the stage 3.

In addition, since the members constituting the film forming apparatus 1 has a machining error within a tolerance range, the dimension L1 of the first gap 81 formed between the lifting shaft 41 and the lid member 71 may be non-uniform in the circumferential direction. In this case, when the purge gas ejected from the non-uniform first gap 81 collides with the rear surface of the stage 3, even if the region where the purge gas collides is viewed along the circumferential direction, the collision amount of the purge gas is non-uniform. As a result, the in-plane uniformity of the heated state of the stage 3 is further deteriorated.

In this regard, in the film forming apparatus 1 of the present disclosure, by installing the guide member 9, it is possible to prevent the purge gas ejected from the first gap 81 from colliding with the rear surface of the stage 3. Therefore, even when the dimension L1 is formed non-uniformly in the circumferential direction, the non-uniform ejection of the purge gas from the first gap 81 is less likely to affect the in-plane temperature uniformity of the stage 3.

### <Evaluation Experiment>

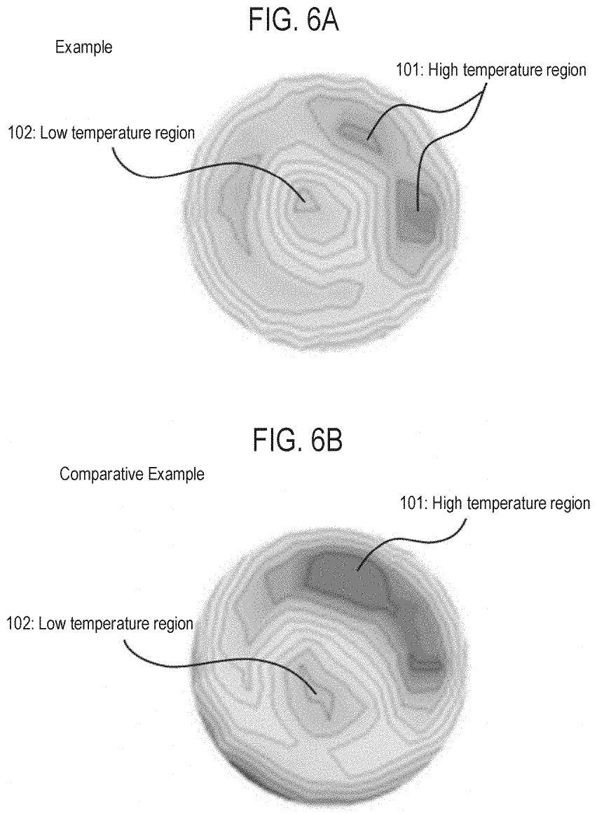

Next, the evaluation of a stage temperature will be described with reference to FIGS. 6A and 6B. In the film forming apparatus 1 illustrated in FIG. 1, N₂ gas as a purge gas was supplied from the purge gas supplier 74 into the processing container 2 at a flow rate of 28 slm. In addition, a wafer having a temperature detection function was placed on the stage 3 heated to 440 degrees C. by the heater 31, and the temperature of the wafer was detected. The wafer having the temperature detection function is configured to be able to detect temperatures at 121 points in the wafer plane. The guide member 9 was configured as described above with reference to FIGS. 1 to 3, wherein the dimension L1 of the first gap 81 was set to 2 mm, the dimension L2 of the second gap 82 was set to 2 mm, the dimension L3 of the third gap 83 was set to 5 mm, and the pressure in the processing container 2 was set to 45 Pa (example). In addition, the same evaluation was also performed for the configuration that did not include the guide member 9 (comparative example).

The results of the example are shown in FIG. 6A, and the results of the comparative example are shown in FIG. 6B. The actual measurement results are presented as color images in which different colors are assigned to different temperature ranges of the wafers, but FIGS. 6A and 6B show the results of grayscale conversion of the images. In the drawings, high temperature regions 101 having the highest temperature and low temperature regions 102 having the lowest temperature are designated by reference numerals, respectively.

Referring to the results of the example of FIG. 6A, it was recognized that the center of the wafer is the low temperature region 102, and the peripheral edge is the high temperature region 101, and that the in-plane temperatures of the wafer are changed substantially concentrically and the temperature fluctuation is small. In the film forming process, it is preferable that the temperature distributions of the wafer are concentric. Thus, it was confirmed that temperature distributions suitable for the film forming process are formed. From the results of the comparative example of FIG. 6B, the high temperature region 101 and the low temperature region 102 are locally present, the temperature distributions are not concentric, and non-uniform temperature distributions are formed along the circumferential direction. In addition, temperature differences in the wafer plane are also large.

From the results of the example and the comparative examples, it is understood that the in-plane temperature uniformity of a wafer greatly differs depending on the presence or absence of the guide member 9, and that it is possible to improve the in-plane temperature uniformity of a wafer by providing the guide member 9. In the results of FIG. 6B, it was recognized that since the low temperature region 102 is locally present, the temperature drops on the rear surface of the stage 3 to which the purge gas has been reached, and the stage temperatures are directly reflected on the wafer. In addition, referring to the results of FIG. 6B, it can be seen that the low temperature region 102 is concentrated at one side of the wafer 10. As described above, it is presumed that due to the mounting tolerance between the lifting shaft 41 and the lid member 71, the ejected amount of the purge gas becomes non-uniform in the circumferential direction, which is reflected in the temperatures of the wafer via the temperatures of the stage so that biased temperature distributions are formed on the wafer.

Meanwhile, in the same film forming apparatus 1 provided with the guide member 9, the in-plane uniformity of wafer temperatures is improved as shown in FIG. 6A. From this, it is understood that, even when the ejected amount of the purge gas becomes non-uniform in the circumferential direction due to the mounting tolerance between the lifting shaft 41 and the lid member 71, the stage temperature may be less affected by providing the guide member 9.

In addition, fluid simulations of purge gases were performed for the example and the comparative example. The results of these simulations were similar to the flows of purge gases described with reference to FIGS. 4 and 5. That is, in the configuration of the embodiment, the flow velocity of the purge gas flowing through the third gap 83 was small, the flow velocity was further reduced in the bottom area 12, and the flow velocity of the purge gas on the rear surface of the stage 3 was about 0.3 m/s. In the configuration of the comparative example, since the purge gas was ejected toward the stage 3 at a large flow velocity through the first gap 81, the flow velocity of the purge gas colliding with the rear surface of the stage 3 was about 6 m/s at the maximum. As described above, from the results of the fluid simulations, it is recognized that, by providing the guide member 9, the flow velocity of the purge gas in the vicinity of the rear surface of the stage 3 decreases and the purge gas has little effect on the temperature of the stage 3.

In addition, in the configuration of the example and the configuration of the comparative example, the wafers 10 were placed on the stages 3, W films were formed through the above-described method by using WCl₅ gas and H₂ gas as reaction gases, and using N₂ gas was used as a replacement gas. Then, the in-plane film thickness uniformity was obtained. A film was formed on each of wafers, and the average film thickness was 29 Å. As a result, the in-plane film thickness uniformity of the example was 3.6%, while that of the comparative example was 4.5%. Thus, it was recognized that the in-plane film thickness uniformity is improved by the configuration of the example. In addition, film formation on the rear surface of the stage 3 was not visually recognized, and it was confirmed that the supply of the purge gas to the bottom area 12 suppresses the infiltration of reaction gases into the rear surface of the stage 3.

Although the first gap 81 and the second gap 82 were set to the same dimension in the example, the example is improved compared with the comparative example in terms of in-plane temperature uniformity or in-plane film thickness uniformity of a wafer. Therefore, when the dimension L1 of the first gap 81 is set to be smaller than the dimension L2 of the second gap 82, further improvement in the in-plane temperature uniformity or in-plane film thickness uniformity of a wafer can be expected.

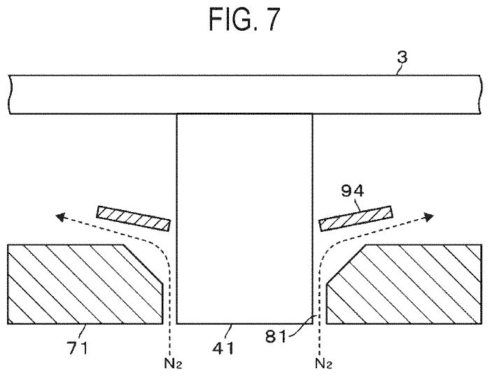

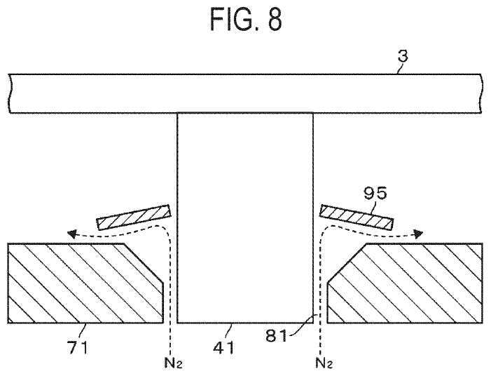

In the embodiment described above, the guide surface of the guide member does not necessarily have to be disposed to face the flange of the lid member 71. For example, as illustrated in FIGS. 7 and 8, the guide members 94 and 95 configured with annular plate-shaped members may be disposed to be inclined with respect to the lid member 71. The example illustrated in FIG. 7 is an example in which the guide member 94 is disposed such that the guide member 94 has the height position of the outer edge that is higher than that of the inner edge. In addition, the example illustrated in FIG. 8 is an example in which the guide member 95 is disposed such that the guide member 95 has the height position of the outer edge that is lower than that of the inner edge. In these cases, the dimensions of the portions in which the bottom surfaces of the guide members 94 and 95 and the top surface of the lid member 71 are closest to each other are the dimension L3 of the third gap. Even if the guide members 94 and 95 are disposed in this way, the purge gas that has flowed into the processing container 2 through the first gap 81 is guided to flow away from the direction toward the rear surface of the stage 3 by the guide surfaces of the guide members 94 and 95 as indicated by the broken lines in the drawings.

The guide member are not necessarily limited to an annular member. Small piece-shaped members may be arranged side by side at a position above the lid member 71 to surround the periphery of the lifting shaft 41, and to make a set of the rear surfaces of the small piece-shaped members form the guide surface. This is because, by reducing the gaps between the small piece-shaped members to increase the pressure loss, it is possible to reduce the momentum of the purge gas flow toward the stage 3 through these gaps to guide the flow of the purge to the lateral side.

When the guide member is configured with an annular member, it is not necessary to form the guide member in a plate shape. The guide member may be a member having the thickness changing in the radial direction, and the guide surface formed on the bottom surface of the guide member may be a curved surface. In addition, the outer edge of the guide member may be disposed at a position inside the edge portion 715 of the opening of the recess 714 of the lid member 71. In these cases as well, as for the third gap formed between the bottom surface of the guide member and the top surface of the lid member 71, the dimension of the portion in which the guide member and the lid member 71 are closest to each other is the dimension L3 of the third gap. With these guide members, it is possible to guide the flow direction of the purge gas to flow away from the direction toward the rear surface of the stage 3. As a result, it is possible to ensure the high in-plane temperature uniformity of the stage 3, and thus to improve the in-plane uniformity of the film forming process.

The casing is not limited to the bellows 45, and may be configured with, for example, a housing surrounding the entire lifting mechanism 4. Furthermore, it is not always necessary to form the recess 714 in the top surface of the lid member 71. Even when the recess 714 is formed, the recess 714 is not limited to the recess 714 having the tapered surface 713 having the above-described configuration. For example, the recess may be, for example, a notch having a rectangular shape in vertical cross section.

The configuration for supplying reaction gases to the film forming apparatus is not limited to the shower head, and may be a single opening. In addition, the method of forming a film on the surface of a wafer in the film forming apparatus is not limited to an ALD method. The present disclosure is also be applicable to a film forming apparatus that executes a CVD method. In conducting the CVD or ALD, plasma may be used as a means for activating the reaction gases.

When forming a W film with the above-disclosed film forming apparatus 1, a tungsten hexachloride (WCl₆) gas may be used as the raw material gas in addition to the WCl₅ gas, and as a reducing gas, monosilane (SiH₄) gas, diborane (B₂H₆) gas, ammonia (NH₃) gas, phosphine (PH₃) gas, and dichlorosilane (SiH₂Cl₂) gas may be used in addition the H₂ gas.

The embodiments disclosed herein should be considered to be exemplary in all respects and not restrictive. The embodiments described above may be omitted, replaced, or modified in various forms without departing from the scope and spirit of the appended claims.

According to the present disclosure, when a substrate is placed on a stage heated by a heater to perform a film forming process, it is possible to improve the in-plane uniformity of the film forming process.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An apparatus for forming a film on a substrate, the apparatus comprising:
a processing container in which a reaction gas is supplied to a surface of the substrate in a vacuum atmosphere to perform a film forming process;
a stage installed in the processing container, configured to place the substrate thereon, and including a heater configured to heat the substrate;
a lifting shaft installed to extend in a vertical direction while supporting the stage from a bottom surface side of the stage, and connected to an external lifting mechanism via a through port formed in the processing container;
a casing installed between the processing container and the lifting mechanism and covering a periphery of the lifting shaft;
a lid member disposed to surround the lifting shaft with a gap interposed between a side peripheral surface of the lifting shaft and the lid member, and installed in the processing container over an entire circumference such that communication between a lower side space and an upper side space of the lid member is blocked in a portion other than the gap;
a purge gas supplier configured to supply a purge gas into the casing; and
a guide member disposed at a position facing an end portion of the gap that opens toward an interior of the processing container and including a guide surface configured to guide the purge gas supplied to the casing such that the purge gas flows into the processing container through the gap and then flows away from a direction toward a rear surface of the stage.

2. The apparatus of claim 1, wherein, when the gap interposed between the side peripheral surface of the lifting shaft and the lid member is referred to as a first gap, the guide member is an annular member that is disposed to surround the lifting shaft with a second gap, which is a gap formed between the guide member and the side peripheral surface of the lifting shaft, and is formed such that a dimension of the second gap is smaller than a dimension of the first gap.

3. The apparatus of claim 2, wherein a ratio of the dimension of the first gap to the dimension of the second gap is a value within a range of more than 1 and equal to or smaller than 2.5.

4. The apparatus of claim 3, wherein the guide member is disposed at a position above the lid member with a third gap, which is a gap formed between the guide surface and a top surface of the lid member, and disposed such that a dimension of the third gap is larger than the dimension of the second gap.

5. The apparatus of claim 4, wherein a ratio of the dimension of the third gap to the dimension of the second gap is a value in a range of 1.5 to 3.5.

6. The apparatus of claim 5, wherein the lid member includes a recess formed on the top surface of the lid member and including a tapered surface having an opening diameter increasing from a lower side toward an upper side, and
wherein the guide member is disposed to cover an opening of the recess when viewed from a top surface side, so that a vortex of the purge gas is formed in a space between the guide member and the recess.

7. The apparatus of claim 6, wherein the guide member includes an outer edge disposed at a position outside an edge portion of the opening of the recess.

8. The apparatus of claim 1, wherein the lid member includes a recess formed on a top surface of the lid member and including a tapered surface having an opening diameter increasing from a lower side toward an upper side, and
wherein the guide member is disposed to cover an opening of the recess when viewed from a top surface side, so that a vortex of the purge gas is formed in a space between the guide member and the recess.

9. A method of forming a film on a substrate by using an apparatus including:
a processing container in which a reaction gas is supplied to a surface of the substrate in a vacuum atmosphere to perform a film forming process;
a stage installed in the processing container, configured to place the substrate thereon, and including a heater configured to heat the substrate;
a lifting shaft installed to extend in a vertical direction while supporting the stage from a bottom surface side of the stage, and connected to an external lifting mechanism via a through port formed in the processing container;
a casing installed between the processing container and the lifting mechanism and covering a periphery of the lifting shaft;
a lid member disposed to surround the lifting shaft with a gap interposed between a side peripheral surface of the lifting shaft and the lid member, and installed in the processing container over an entire circumference such that communication between a lower side space and an upper side space of the lid member is blocked in a portion other than the gap; and
a guide member disposed at a position facing an end portion of the gap that opens toward an interior of the processing container and including a guide surface configured to guide a flowing direction of gas,
wherein the method comprises:
heating the substrate placed on the stage;
supplying a purge gas into the casing during a period in which the substrate is being heated, and
guiding a flow of the purge gas by the guide surface of the guide member such that the purge gas supplied into the casing flows into the processing container through the gap and then flows away from a direction toward a rear surface of the stage.
